(19) United States
(12) Patent Application Publication
(10) Pub. No.: US 2025/0133885 A1
(43) Pub. Date: Apr. 24, 2025

(54) VEHICULAR DISPLAY ELEMENT HAVING A HIGH DENSITY LED ARRAY

(71) Applicant: Autosystems, a division of Magna Exteriors Inc., Aurora (CA)

(72) Inventor: Edward Bailey, Rochester Hills, MI (US)

(21) Appl. No.: 18/987,945

(22) Filed: Dec. 19, 2024

Related U.S. Application Data
(62) Division of application No. 17/249,879, filed on Mar. 17, 2021.
(60) Provisional application No. 62/990,719, filed on Mar. 17, 2020.

(51) Int. Cl. H10H 20/855; B60Q 1/04; B60Q 3/60; F21S 41/141; F21S 43/14; H10H 20/01; H10H 20/812; H10H 20/82; H10H 20/841; H10H 20/851

(52) U.S. Cl. CPC H10H 20/855; B60Q 1/04; B60Q 3/60; H10H 20/01; H10H 20/01335; H10H 20/018; H10H 20/812; H10H 20/82; H10H 20/841; H10H 20/8514; B60Q 2400/20; F21S 41/141; F21S 43/14; H10H 20/0361

(57) ABSTRACT

A vehicular lighting system includes at least one light emitting diode chip mini-pixel that has (i) a multi-quantum well stack electrified by a p-type material, an n-type material, and a plurality of electrodes, (ii) a nano-pattern light extractor and (iii) a lateral light confinement distributed Bragg reflector mirror. The at least one light emitting diode chip mini-pixel emits light to illuminate an area exterior or interior of a vehicle equipped with the vehicular lighting system.

### CROSS REFERENCE TO RELATED APPLICATIONS

The present application is a division application of U.S. Non-Provisional patent application Ser. No. 17/249,879, entitled “VEHICULAR DISPLAY ELEMENT HAVING A HIGH DENSITY LED ARRAY,” filed Mar. 17, 2021, which claims priority to U.S. Provisional Application Ser. No. 62/990,719, entitled “VEHICULAR DISPLAY ELEMENT COMPRISING HIGH DENSITY MINI-PIXEL LED ARRAY,” filed Mar. 17, 2020, the contents of each are incorporated herein by reference in their entirety.

### FIELD OF THE INVENTION

The present invention relates generally to a vehicular display element for a vehicle and, more particularly, to a vehicular display element that utilizes high density mini-pixel light emitting diodes (LEDs).

### BACKGROUND OF THE INVENTION

Light emitting diodes (LEDs) have a greatly increased lifespan versus incandescent filaments. This has given LEDs a wide use in automotive applications.

### SUMMARY OF THE INVENTION

The present invention provides a vehicular lighting system for a vehicle that includes at least one light emitting diode chip mini-pixel that includes a multi-quantum well stack electrified by a p-type material, an n-type material, and a plurality of electrodes. The at least one light emitting diode chip mini-pixel also includes a nano-pattern light extractor and a lateral light confinement distributed Bragg reflector mirror. The at least one light emitting diode chip mini-pixel emits light to illuminate an area exterior of the vehicle.

These and other objects, advantages, purposes and features of the present invention will become apparent upon review of the following specification in conjunction with the drawings.

### BRIEF DESCRIPTION OF THE DRAWINGS

FIG. 1 is a plan view of a vehicle with a vision system that incorporates cameras and light sources in accordance with the present invention;

FIGS. 2A and 2B are elevation views of a vehicle depicting advanced lighting display modules in accordance with the present invention;

FIG. 3 is a perspective view of a low to mid-power LED assembly;

FIG. 4 is a plan view of a high power chip scale package;

FIG. 5 is a cross-sectional view of a high power chip scale package;

FIG. 6 is another cross-sectional view of a different high power chip scale package;

FIG. 7 is a flow chart showing the steps for a production process of phosphor converted chip scale package LEDs;

FIG. 8 is a plan view of LED chip mini-pixel with a multi-quantum well stack and with a lateral light confinement distributed Bragg reflector in accordance with the present invention;

FIG. 9A is a top view of the light extraction and lateral structure of a 3-sided LED chip geometry;

FIG. 9B is a partial view of the light extraction and lateral structure of the 3-sided LED chip geometry of FIG. 9A;

FIG. 10 is a cross-section of the light extraction and lateral confinement stack layer structure of a 3-sided LED chip geometry;

FIG. 11 is a process flow chart utilized in the production of phosphor converted 3-sided LED chips;

FIG. 12A is a top view of the light ray behavior of a square 4-sided LED chip;

FIG. 12B is a top view of the light ray behavior of a triangular 3-sided LED chip;

FIG. 13 is a top and bottom view of phosphor coated 3-sided LED chips;

FIG. 14 is a view comparing square chip and 3-sided wafer utilization, device design and dicing pattern;

FIG. 15 is a plan view comparing prior art technologies with new higher density mini-pixel LED chip arrays;

FIG. 16 is a plan view of alternate arrangements of 4-sided and 3-sided LED chip;

FIG. 17 is a plan view of a square mini pixel array comprised of 12×12 elements and micro-controller;

FIG. 18 is a plan view of a horizontal structure of a 3-sided LED chip geometry;

FIG. 19 is a perspective view of a vertical structure of the 3-sided LED chip;

FIG. 20 is a perspective view of an alternative construction of the 3-sided LED chip with a nano-roughened texture;

FIG. 21 is a plan view of a process of producing the 3-sided LED chips;

FIG. 22 is a plan view of a device design and dicing pattern with a wafer;

FIG. 23 is a plan view of a progression of higher luminance chips;

FIG. 24 is a plan view of alternate arrangements of the 3-sided LED chip; and

FIG. 25 is a plan view of a square mini pixel array comprised of 12×12 elements.

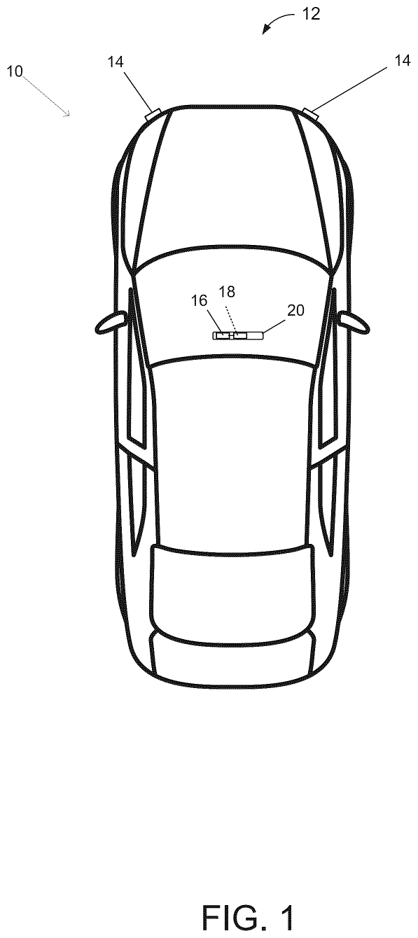

### DESCRIPTION OF THE PREFERRED EMBODIMENTS

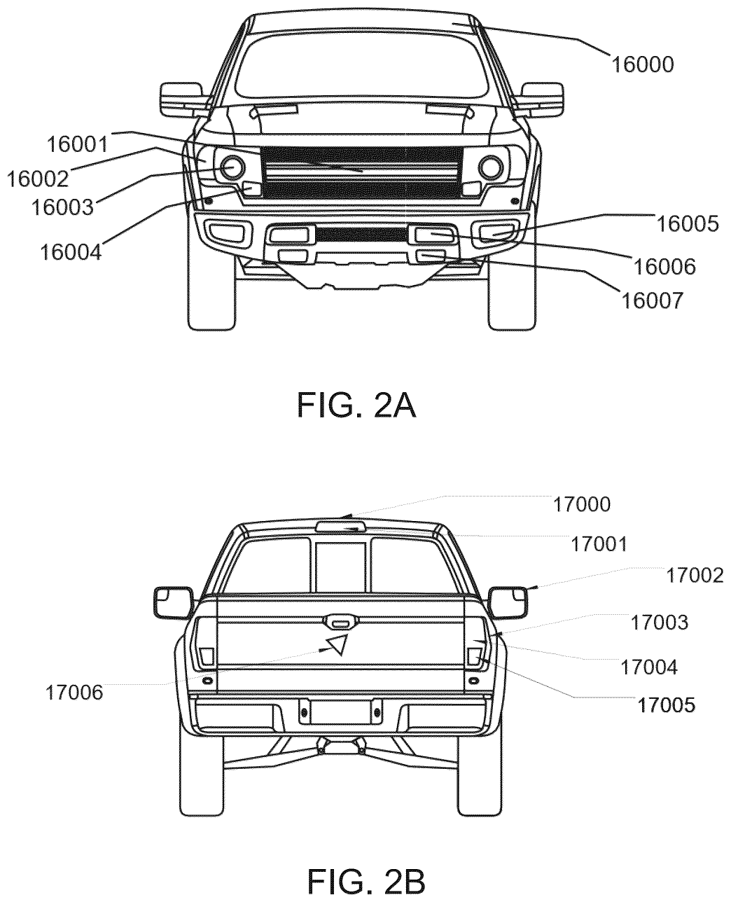

A vehicle lighting system and/or vehicle display element operates to emit light to illuminate an area interior or exterior of the vehicle. Referring now to the drawings and the illustrative embodiments depicted therein, a vehicle 10 includes a vehicle light system 12 with at least one display element 14 such as headlight or turn signal. The lighting system 12 includes a control or electronic control unit (ECU) 18 having electronic circuitry and associated software, with the electronic circuitry including a data processor that is operable to control the display element. FIG. 2A illustrates a next generation advanced lighting system comprised of display element tiles installed on the front of an electric truck 16000. Lighting display elements include lighted display grilles 16001, animated running and signal lights 16002, dynamic head light LED arrays 16003, dynamic marker, signal, and hazard lights 16004, animated display fog light systems, secondary fog lights 16006, and projection fog and hazard lights 16007. As discussed in more detail below, each system may include combinations of mini or micro-LED pixels, cluster light tiles, optical systems, electronic drivers and sensors. By distributing light across the mini-pixel array a reduction in required diffusers may be possible thereby reducing overall power consumption.

Referring now to FIG. 2B, a next generation advanced lighting system includes display element tiles installed on the rear of an electric truck 17000. Lighting display elements include center high mounted stop 17001, driver assistance lights for blind spot and proximity, turn signal 17002 and animated projection of pictorials on the ground or proximity of the vehicle. Additionally, animated tail, and stop lights 17004, reverse lights 17005, and emblems 17006 can be enhanced by means of high luminance mini-pixels. Each lighting system has a primary function for safety, and secondary function to include messaging, warnings, navigation, guidance, weather, and social communication.

Light emitting diodes (LEDs) offer long operating life of, for example, 50,000 to 100,000 hours (as compared to 500 to 1500 hours for incandescent filaments) and cost reductions on vertical flip-chip LED devices has enabled the application of the LEDs to a wider range of operating conditions tailored to automotive, mobility, and military applications. Over the operating life of a vehicle (e.g., 10 to 20 years), inorganic LEDs offer a preferred solution for producing reliable high luminance (i.e., candela/m²) white light through violet, blue, and cyan chip pumped phosphors. Low-cost 5630, and 3030 packaged LEDs in general lighting have dominated as cost reductions further allow adoption of solid-state lighting technology in the market place, which approached 57 percent in 2019. However, a number of design choices inhibit the luminance of packaged LEDs, which prevents their use in high definition micro-LED lighting for automotive applications such as, for example, dynamic daytime running lights (DRL), high definition adaptive driving beam headlights (ADB), and animated rear combination lamps (RCL).

Low power packaged LEDs offer an industry proven alternative to incandescent heater filaments for mobile, vehicular applications where latency to full brightness signal to alert driving attention to action can become a safety concern. Implementations herein overcome the luminance drawbacks of the larger emission area of the chip in the phosphor tub approach and produce higher luminance display capability through a monolithic wafer level wavelength conversion.

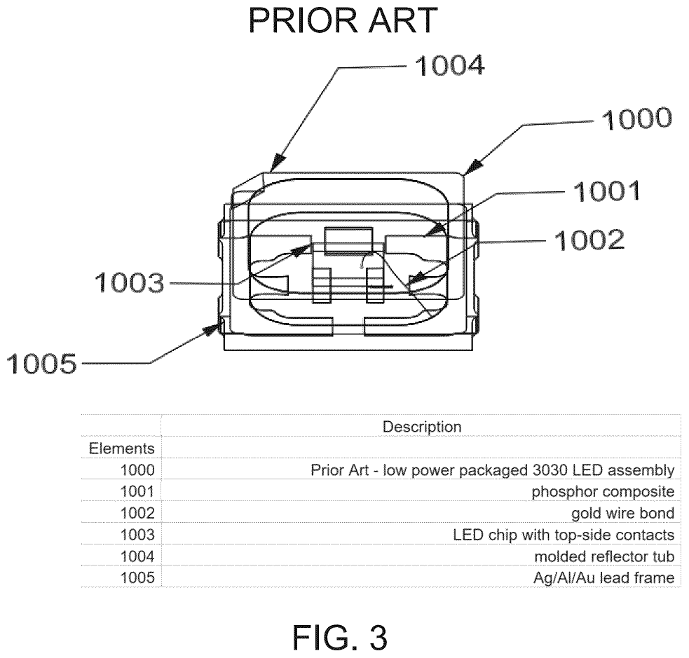

Referring now to FIG. 3, a known low to mid-power 3030 packaged LED assembly 1000 includes an LED chip with a top side contact 1003 which produces blue pump light that is partially absorbed through a phosphor composite 1001. The gold wire bond 1002 electrifies the devices and the wavelength converted light recycles throughout the molded reflector tub 1004. Power and some thermal dissipation is provided by the Ag/Al/Au-plated lead frame 1005. The disadvantage to 3030 packaged LED is that the area of the light source as reflected by the package, the additional cost of the packaging, and the minimum pitch density possible with the package.

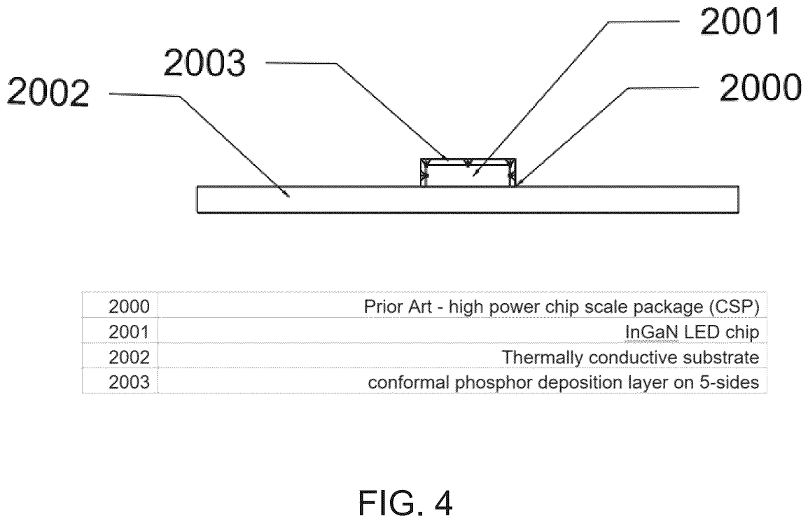

FIG. 4 depicts a known high power chip scale package (CSP) 2000 in which a InGaN LED chip 2001 pumps a conformal LED phosphor applied to all outer facing sides of the chip 2003. The heat produced by both the phosphor and the chip conducts downward through the thermally conductive substrate 2002. Disadvantages to a high power chip scale package include the lateral emissions of the phosphor which decreases luminance. Another disadvantage is the chip to chip light bleed which causes lateral chips to illuminate which reduces pictorial definition.

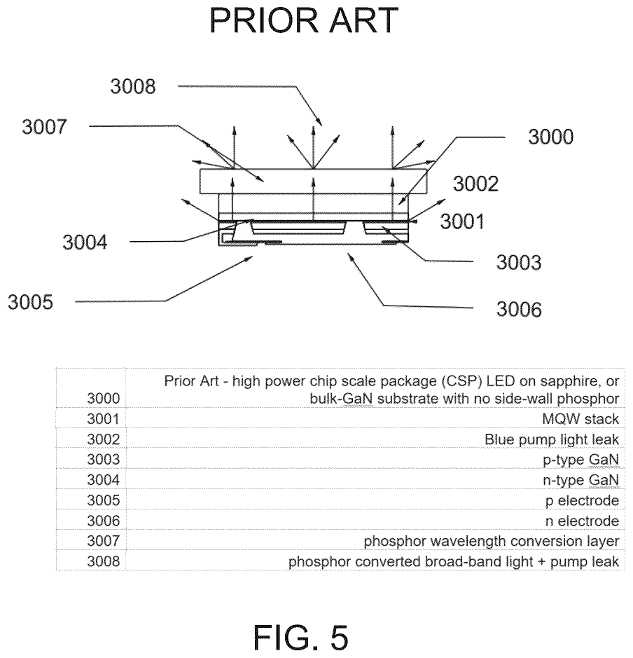

FIG. 5 depicts a known high power chip scale package 3000 in which an InGaN LED chip is not phosphor converted on all 5 sides. Light generates in the multiple-quantum well stack 3001 and then the pump light 3002 leaks laterally through the sides. The device structure comprises p-type GaN 3003, n-type GaN 3004, and electrification through a p-type electrode 3005 and n-type electrode 3006. The top side only phosphor conversion layer 3007 converts the blue pump light into broad band spectra which emits outward 3008. A primary disadvantage to only phosphor converting the top layer is that the color uniformity suffers as scanned by angle from cool white in the center to green on the corners to edges which would appear blue. Luminous efficacy also reduces as blue light has lower luminous efficacy than white.

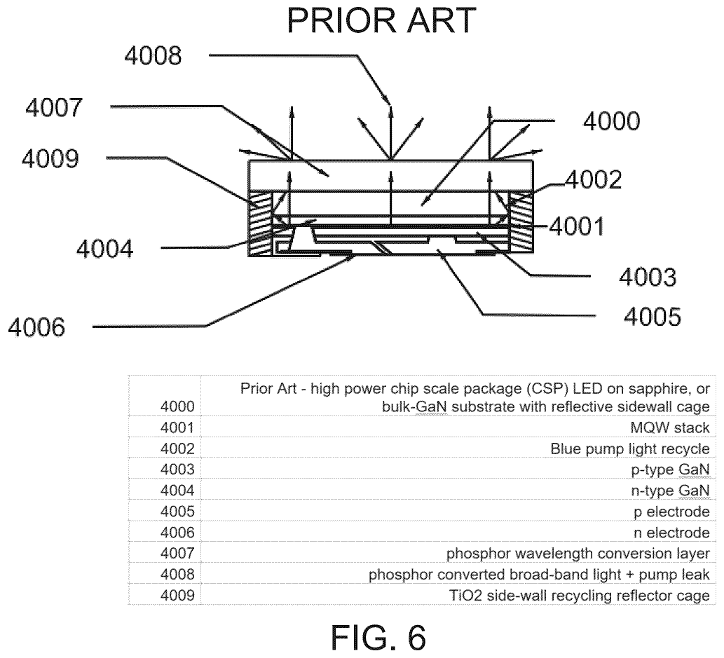

Referring now to FIG. 6, a known high power chip scale package LED 4000 is constructed of a multiple quantum well stack 4001 surrounded on a top side by an n-type GaN 4004 material and a p-type GaN 4003 on the bottom and a blue pump light recycle 4002. Electrification provided by a p electrode 4005 and an n electrode 4006. The device includes a top-side phosphor conversion layer 4007 and includes additional side-wall reflecting material 4009 which recycles light back inward to give it the opportunity to change direction cosines into an upward direction for re-absorption by the phosphor 4007. Broad-band spectrum light 4008 combines with leaked pump light to create white light. This device produces good white light uniformity, higher luminance, and is commercially available. The disadvantages include the processing cost of the deposition of the reflecting material, and the minimum width of the reflecting material to achieve a high luminance top side emitting pixel.

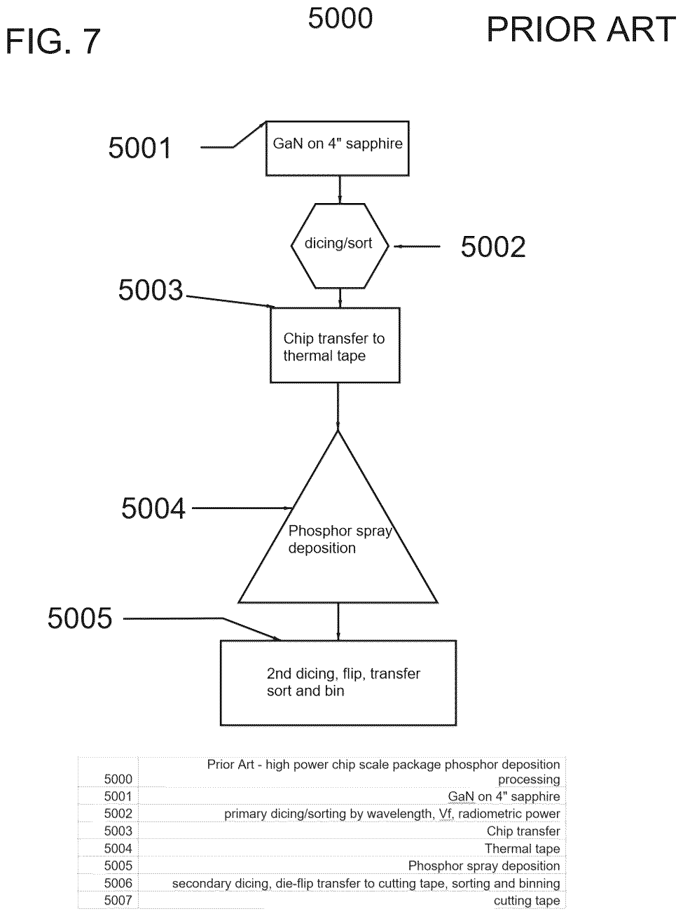

FIG. 7 illustrates a production process 5000 of phosphor converted chip scale package (CSP) LEDs. First, GaN is grown on sapphire 5001, and after completing device structure manufacture the chips are diced, sorted by wavelength, and binned according to voltage Vf and radiometric power 5002. The chips are transferred 5003 to thermal tape in preparation for the application of phosphor 5004. After curing the phosphor 5004, a secondary dicing, die flip and transfer to cutting tape 5005 is performed in addition to die chip sorting and binning 5005.

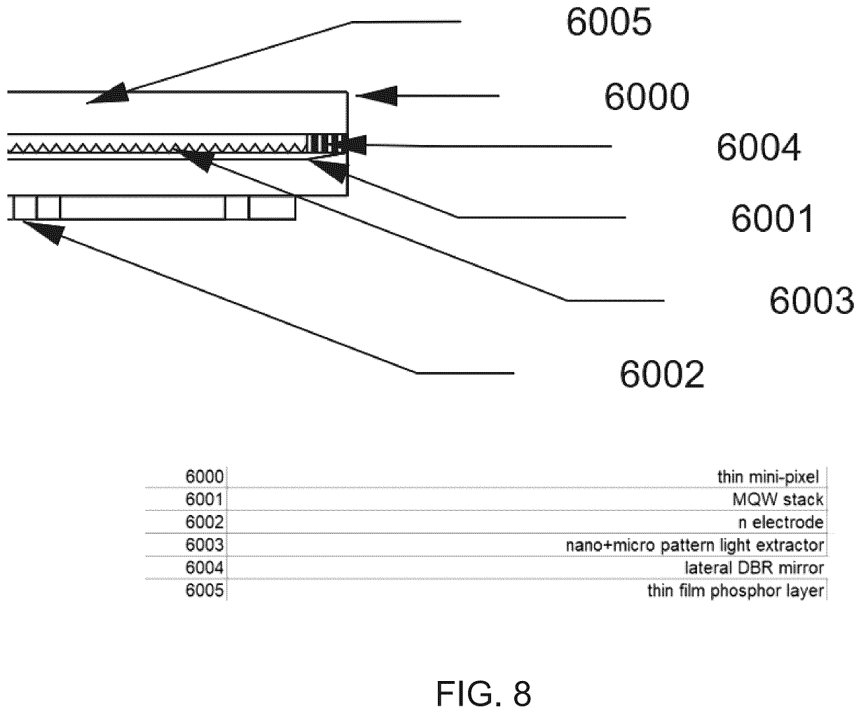

FIG. 8 illustrates a new LED chip mini-pixel 6000 in which a multi-quantum well (MQW) stack 6001 is electrified by means of p-type and n-type material and electrodes 6002. The device includes a nano roughened+micro-pattern light extractor 6003 which scatters light to help enable higher light extraction from the top of the chip and a lateral light confinement distributed Bragg reflector (DBR) mirror 6004 to increase luminance and reduce side pump light leak to force light upward through the thin film phosphor layer 6005, which is applied directly to the undoped GaN. In terms of phosphors 6005, many materials are preferred including YAG, Si3N4, GAL, and KSF. Quantum dots may also be used for conversion of light to broadband spectra. Feature sizes for the nano-roughness, micro-pattern light extractor 6003 may be on a scale from 500 nm to 10 μm and of varying aspect ratio width/height which can be optimized through finite-difference time domain analysis to improve light extraction for different colors violet, blue, cyan, including yellow to red. Generally an aspect ratio of 3:1 functions quite well and primitive shapes of tapered hexagons, pyramids, cones, and others can be manufactured on sapphire. Means of manufacturing the micro light extractors on sapphire can be accomplished a number of ways including selective laser etching, wet-chem etch with KOH, HF, and polydimethylsiloxane+ICP or inductively coupled plasma. Tetramethyl ammonium hydroxide can also be used for etching of the substrate material which then serves as a cloning template for the undoped GaN growth. The lateral light confinement distributed bragg reflector 6004 is comprised of alternating pairs of high and low refractive index materials. Low index materials including silicone, SiO₂, MgF₂ or no material at all (air) and high index materials including GaN, Al₂O₃, Ta₂O₅, ZrO₂ may be used, for example. Preferably, the embodiment uses the patterned sapphire substrate to create the foundation upon which the undoped GaN layer is grown. The sapphire template can then be removed by means of UV-excimer process to reveal the GaN micro-structure+lateral confinement pillars unique to the DBR enclosed in this invention. The DBR is then complete when a thin layer of silicone is applied to the finished DBR micro structure+lateral confinement DBR which then forms the required high/low index stack for light reflection.

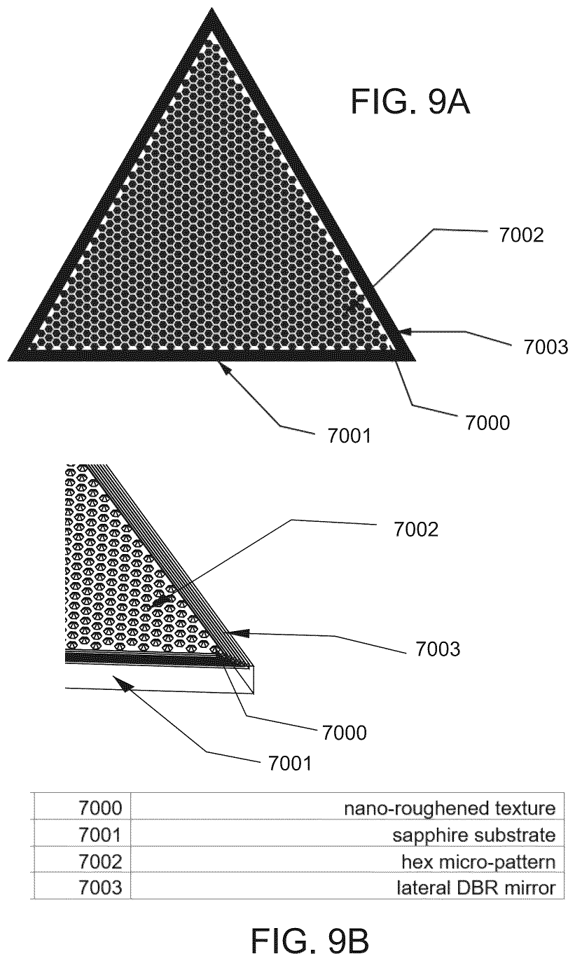

Now referring to FIG. 9A and FIG. 9B, a top view and a partial view of the 3-sided LED chip is illustrated with integrated nano roughness features 7000 and micro size light extraction features 7002 and lateral confinement DBR device 7003 as produced on a sapphire substrate 7001 preferably c-plane as a template upon which undoped GaN can be grown. Many alternative materials may be used to create high/low refractive index. For example, undoped GaN alternated with Air n=1.0 may achieve high lateral confinement with less pairs. To protect the LED chip encapsulation with silicone is common and can maintain good transparency over high temperature. To provide more detail, a nano 7000 feature refers to surface roughness features with dimensions less than 1 um which improve scatter behavior which expands the light extraction traversal from layer to layer MQW to n-type GaN to undoped GaN through a thin buffer layer to the silicone encapsulant. Micro-size light features 7002 refer to those greater than 1 um to as large as 10 um which are imprinted by means of pattern tools or etch methods.

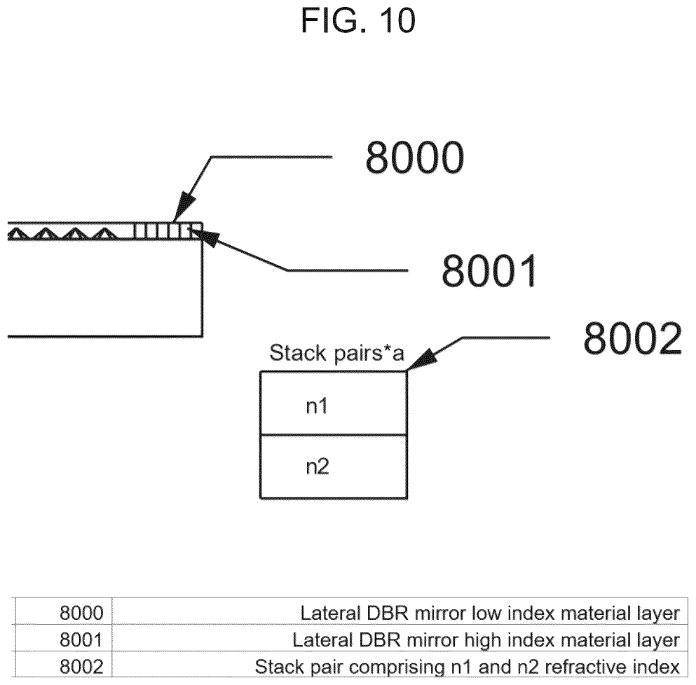

Now referring to FIG. 10, the lateral mirror DBR design 8000/8001 achieves omnidirectional reflection over spectral bandwidth greater than 200 nm for phosphor converted light. For monochromatic colors red and amber, for example, the DBR stack thickness may be reduced as broad band reflection is not necessary. Stacks of refractive index pairs 8002 can range from as few as 4 pairs to 200 pairs. High pair count greater than 100 is not cost effective so it is a great advantage to increase refractive index contrast. Methods of manufacture include laser direct beam drilling, selective laser etch or (ISLE) and multi-photon etching and removal by KOH wet chem process. Dimensions to 1 um or smaller may be achieved and depths to 125 um has been achieved with repeat micro-scanning through photon ablation and pico to femtosecond laser pulse in UV 343 nm to −Grn 514 nm. Bragg reflection can also be accomplished without such regular periodic structures and dielectric “foam” nano-porous structures are now possible inspired by carry-over technology from holey fiber drawing for telecommunications in which photonic crystalline air holes enable laser confinement to the core for dense wavelength division multiplexing of signal. For LED applications, single mode transmission is not necessary or desirable. Instead, preferably multi-band confinement of randomly polarized light emerging spontaneously from the active layers and robust materials which can survive environmental cycling as required for automotive are used. The testing standard AEC-Q102 is recommended by the automotive electronics council used for qualifying laser and LED light emitting devices which include various tests of high temperature, wet, high humidity, power cycling in chambers to 85 C and thermal cycling in combination with H2S mixtures and other conditions as required to prove out the structural integrity of the device for long life operation in a vehicle. The materials described herein are tailored to high temperature operation.

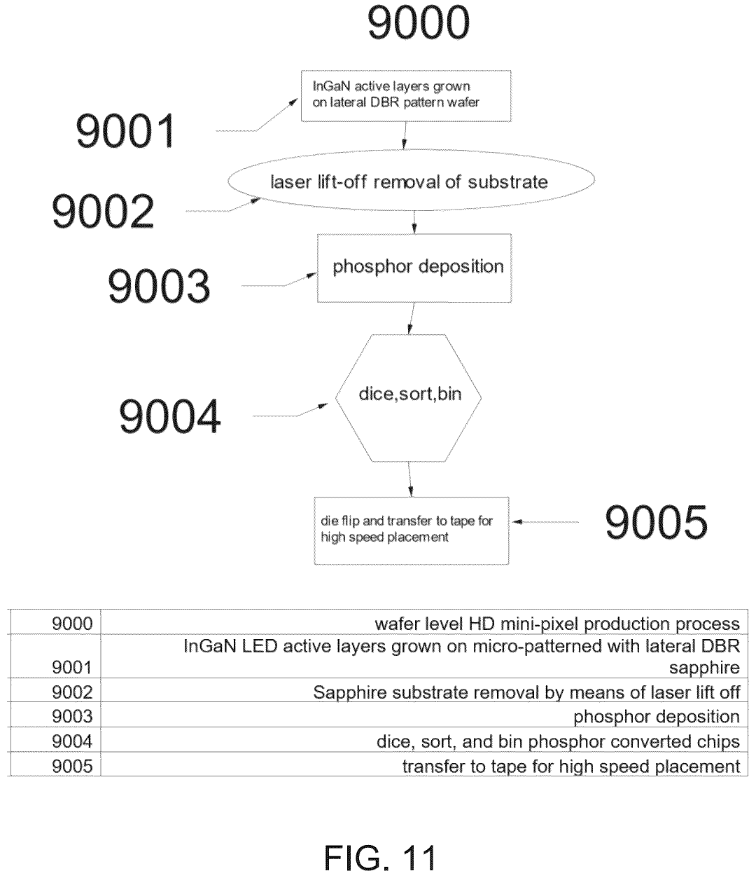

FIG. 11 depicts a process 9000 by which the chips 6000, 7000, 8000 are produced. First, GaN/InGaN is grown on a micro-patterned substrate, for example, 4 inch sapphire substrate 9001 in which the sapphire is modified with combinations of nano-roughening, incorporation of micro light extractors, and lateral energy confinement features. Laser lift off (LLO) at 9002 removes the sapphire substrate leaving free-standing undoped GaN lateral confinement DBR features above n-type GaN and the InGaN/GaN active layers. Phosphor deposition on the free-standing GaN wafer then requires dice, sort and binning according to CRI, CCT, dominant wavelength, radiometric power, luminous flux and voltage. The finished LED chips are then transferred to tape 9005 for die separation (stretch) and loading into carriers for precision placement to a PCB.

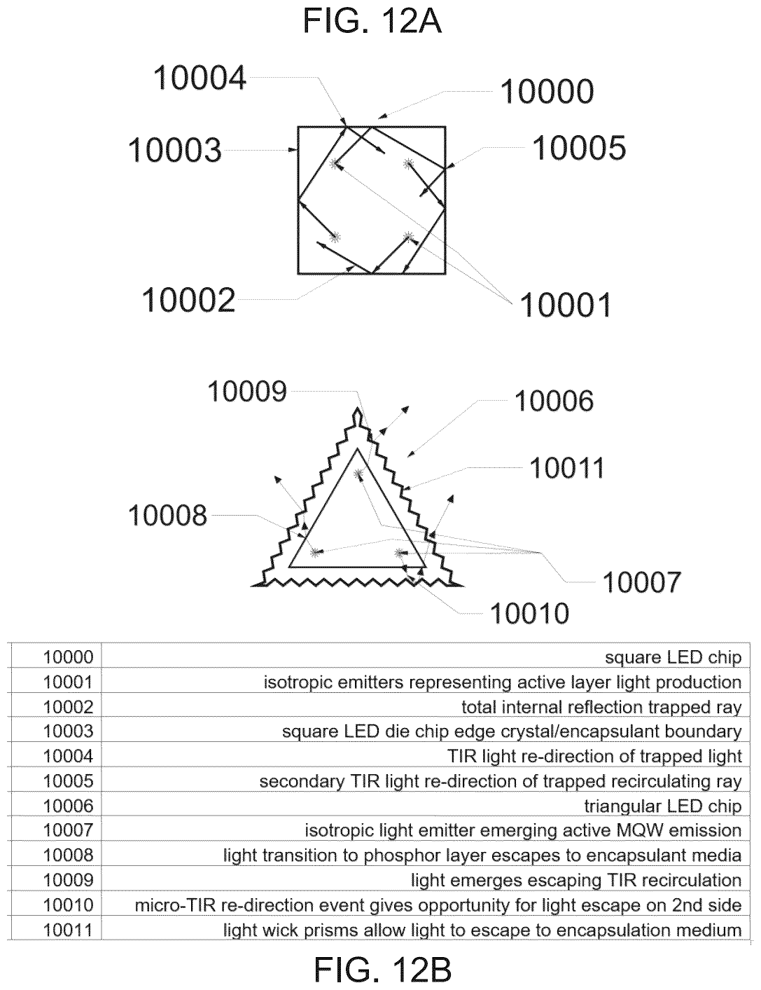

FIG. 12A illustrates device raytracing of typical 4-sided construction of the LED 10000 in which the square light emitting device includes an active light emission layer approximated by means of an array of isotropic emitters 10001. Included is the raytrace path of light confinement by hampered by unwanted lateral total internal reflection (TIR). The square edges 10003 of the chip trap the light laterally within the chip. Total internal reflection rays 10002, 10004, and 10005 show how light ray paths at less than critical angle defined by the angle at which all light self-reflects within the medium due to the index of refraction difference between GaN, Sapphire, and encapsulants (silicone). FIG. 12B illustrates device raytracing of the 3-sided sapphire chip 10006 that includes a light wicking prism structure 10009 and 10011. Light wicking refers to patterns in the dicing of the chip which encourage the lateral light emerging from isotropic emitters 10007 to escape the chip thereby increasing luminous efficiency of the chip. A feature illustrated by the boundary of 10008 shows a transition from the GaN/InGaN active structure to a layer of phosphor and encapsulation material. For monochromatic LED chips, no phosphor layer is required and the boundary layer shown would depict a sapphire to air interface. The light wick prism structure works in both conditions both with phosphor conversion layers and without as would be required for red or yellow LEDs. Rays emerging from 10010 shows the advantage of the 3-sided chip in which a light wick prism reflection of the rays permits recycling of the light ray to an escape path through a second side of the chip a ray behavior which is not possible with a 4-sided chip. The micro-patterning on the sapphire can help reduce threading dislocations in undoped and n-type GaN. The combined optical features of the hexagonal micro patterns improve external quantum efficiency and thereby reduce the power required to produce essential lighting functions for transportation vehicles.

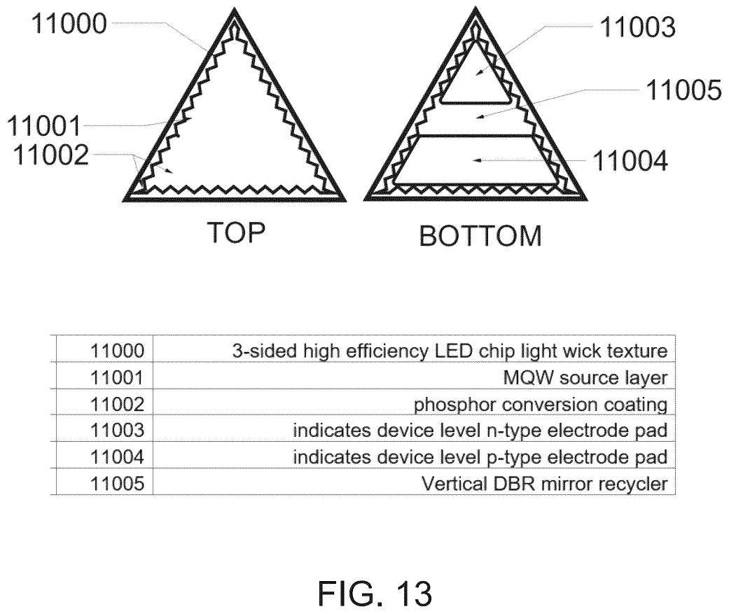

FIG. 13 illustrates a new 3-sided high efficiency LED chip enhanced with light wick prism texture 11000. In this embodiment lateral confinement DBR structures are not required as lateral extraction prevails. DBR structures 11005 are applied for vertical recycling instead. Vertical direction refers to light recycling in the Z+ direction in Z+ refers to light orthonormal to the top exiting surface of the LED chip. The +Z is the direction required for high intensity light. The LED in this embodiment requires MQW source layer 11001 comprised of periodic layers of InGaN/GaN. The active MQW is electrified for light production by means of p-type 11004 and n-type 11003 layers. These layers are directly coupled to p-type 11004 and n-type 11003 pads on the bottom surface of the LED. The n-type pad 11003 illustrated with smaller area an alternate construction may equalize the contact area of both p-type and n-type pads. Recycling light by means of a vertical DBR mirror recycler 11005 enhances the light available to pump the thin phosphor conversion coating 11002 applied to the top surface and/or to the lateral edges of the device. The light device does not require sapphire laser lift off if the chip and if the device requires greater rigidity, the light wick features may be produced by means of laser writing micro-holes during the dicing process. Rather than using a round Gaussian TEM00 beam, an optic system may convert the beam to a square shape as required to produce square micro-holes prior to dice and separation. The square micro-holes produced through a femto-second photo ablation process using UV or GRN laser light would thereby create the light wick devices directly. Construction of the DBR mirror recycler below the MQW source layer 11001 is produced by alternating high and low refractive index materials. More pairs equals higher reflectance and less directional sensitivity thereby improving spectral bandwidth of reflection. The DBR structure comprising pairs of high/low index materials is simplified when designed for monochromatic light production in blue, green, amber, red, etc. Phosphor spectral recycling is more difficult as the spectral bandwidth of reflection would preferably span from 380 to 780 nm. Ultraviolet and infrared LEDs require special DBR design to produce net gain.

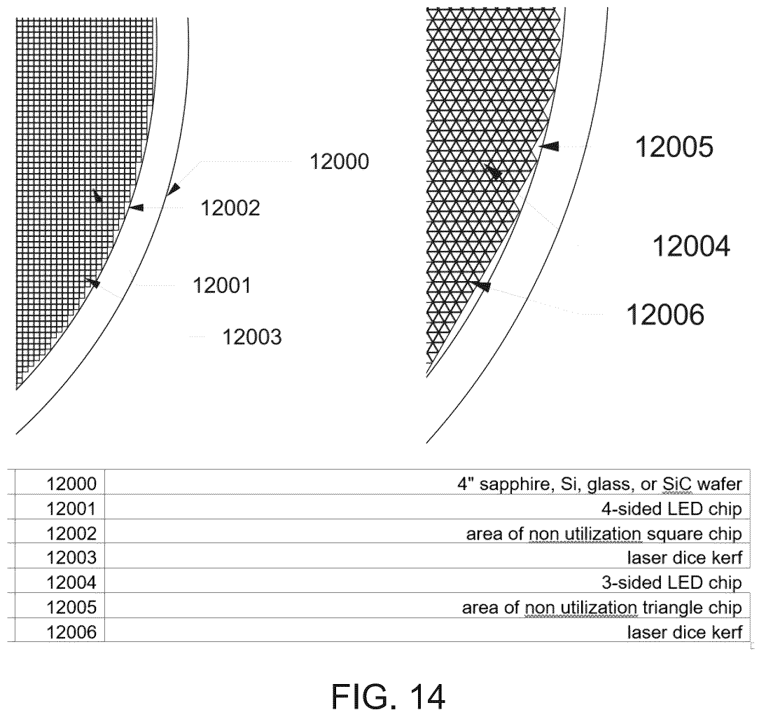

FIG. 14 illustrates a comparison between a 4-sided device design 12001 and dicing pattern in which the LED devices wafer 12000 is typically cut with a min kerf 12003 to produce as high a yield/wafer as possible. As shown, the higher yield/wafer increases as diameter goes up. Hence, the advantage to get to 300 mm Si wafers if lattice mismatch mitigation can be accomplished with sufficient buffer layer growth at high speed. Ideally, the non-utilization area 12002 is reduced so that cost reduction can be made. As shown in FIG. 12004 for a 3-sided chip, the area of the chip in a 3-sided form is equivalent to that of the 4-sided chip, however lower non-utilization area 12005 is achieved by means of geometric patterning and maintaining minimal kerf 12006 between the chips. Non-utilization area for a 2 inch (50 mm) wafer, for example, can be as high as 9 percent for 1 mm² chips falling to less than 2 percent for 8 inch (300 mm) wafers. In state of the art manufacturing systems (e.g., JPSS IX-200) can dice with kerf of 2.5 um or better. As comparison with the 3-sided chip in this embodiment on a 4 inch, 100 mm diameter wafer with 3 mm edge, 23,848 4-sided chips can be produced, whereas 25,339 3-sided chips can be produced with equivalent chip area of 0.23 mm² which translates to a net gain of +6 percent which is close to the yield obtained when going from a 2 inch (50 mm) to a 6 inch (152 mm) substrate diameter. Increased yield results in reduced cost per chip which is advantageous.

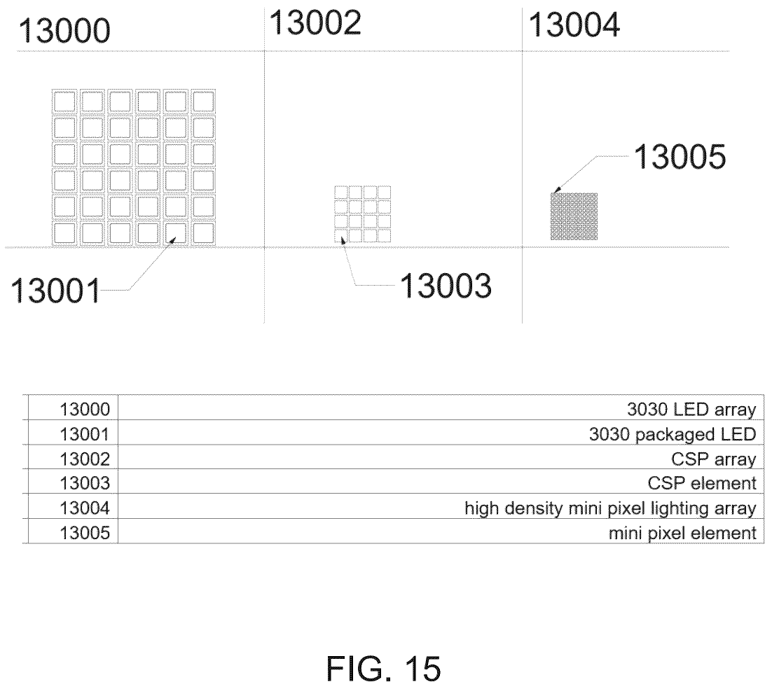

FIG. 15 illustrates how the drive to produce higher luminance/chip has progressed from the larger array 13000 with low cost 3030 LED package 13001, in which the chip is converted to white by means of a tub of phosphor, to the CSP array 13002, in which each CSP chip element 13003 is arrayed into an x,y pattern for illumination. Implementations herein include an improvement for increasing the number of elements/unit area which can be powered with a high density pixel lighting array 13004 that includes many mini pixel elements 13005. When comparing the enclosed mini-pixel arrays in terms of dots per inch (DPI) or addressable light elements/in² of area, a 3030 package yield at best 25.4/3 mm pixel density on a side or 64 light pixels in which “pixel” represents the light emission area of the packaged 3030 LED. A chip scale package at 1 mm element size can yield 25×25 or up to 625 pixels/in², and finally the enclosed mini-pixel arrays at 0.3 mm on a side and 0.17 mm in vertical can yield (25.4/0.3)*(25.4/0.17) or 84*149=12,516 pixels/in² a gain in resolution of 20×. The benefits and advantages of higher fidelity animated pictorials, figures, and more fluid graphics can gain many applications previously not obtainable.

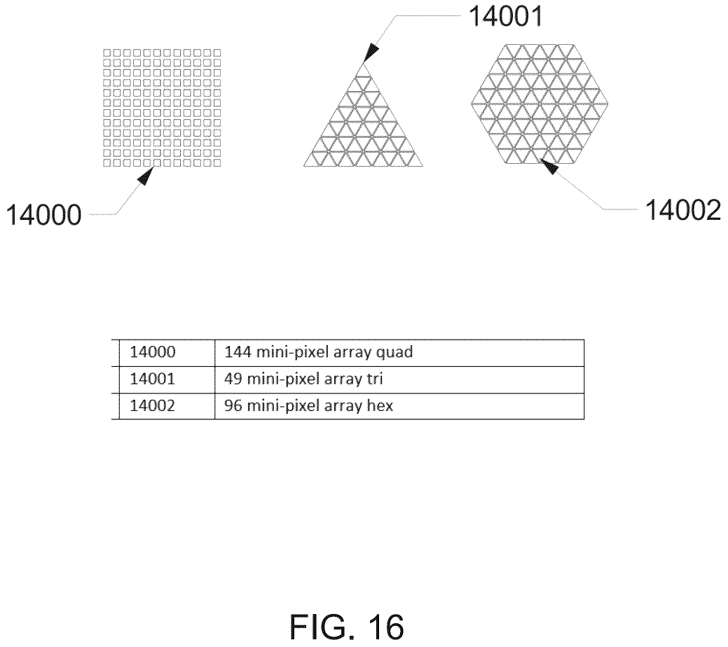

Referring now to FIG. 16, alternate arrangements where, instead of multiple square or rectangular elements arranged to form an individually addressable array 14000 including 144 mini pixels, a 3-sided device structure array pattern allows for triangular array 14001 elements including 49 mini pixels, each of which may be patterned into other shapes and configurations. For example, the shapes include 6-sided clusters such as 14002 that include 96 mini-pixel 3-sided elements. Each of the light pixel elements including the cluster arrays may further include combinations of micro and nano-structure light extraction elements and lateral confinement DBR constructed of either high/low refractive index pair stacks or nano-porous light confinement structures in which the sapphire substrate is etched to produce. Each of the light array elements, whether in square or triangular tiles, can each be tiled together to form larger area displays.

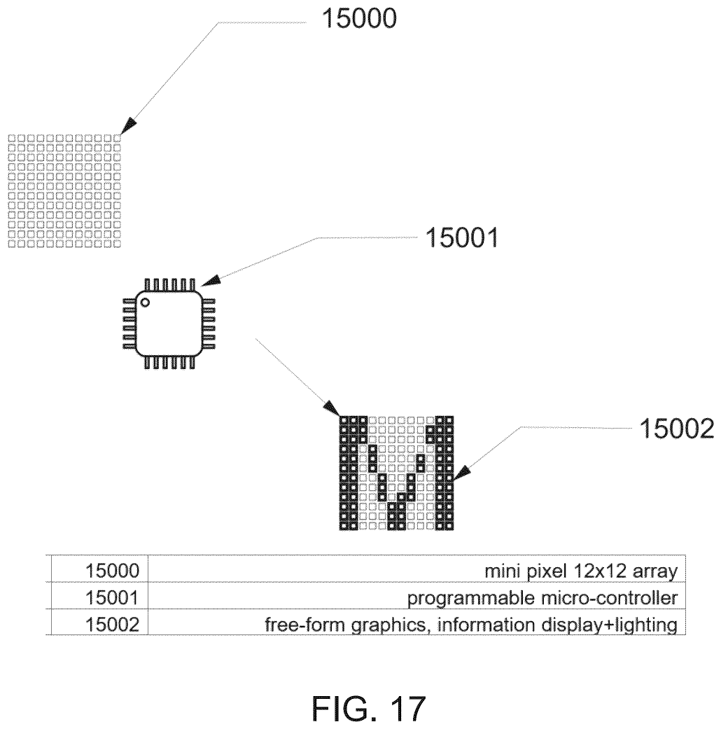

FIG. 17 illustrates how a square mini pixel array 15000 comprised of 12×12 elements may be individually addressed via a programmable micro-controller 15001 to produce free-form graphics, information display (e.g., lettering and figures), and lighting functions such as the letter “M” shown in 15002. In addition the micro-display LED elements can be transferred to an integrated CMOS backplane to provide both control and electronic driver function. Thus allowing what was formally a single pixel element to have a multiplier effect for placement speed. A system originally producing 100 Hz placement of light pixels can now be multiplied by 10 to 2,500× as smaller micro-pixel elements bonded to the Si backplane can be placed by high speed machines. For example, 100 Hz at 100 pixels/tile equals an effective pixel placement rate of 10 kHz at 100 um LED element size. At 50 um LED chip size, 100 Hz*400 pixels/tile achieve an effective placement rate of 40 kHz. Finally, at a device size of 8 μm, 125 pixels/1 mm edge are possible achieving 15,625 pixels/1 mm². When the micro-tiles are placed at 100 Hz, this achieves an effective pixel placement rate of 1.5 MHz. The micro-LED yields over smaller areas is maturing with each passing year. The rework problem becomes less of an issue with the combination of micro-scale device structure where it is strongest and fast placement at device sizes of 1 mm where wafer handling is optimized with current technology. Each integrated smart tile requiring data input and output channel communication and common anode or cathode rings to power each pixel by shift-register. Each tile thereby becomes a light network and by means of persistence of vision effect, multi-scan can improve the pixel drive bandwidth.

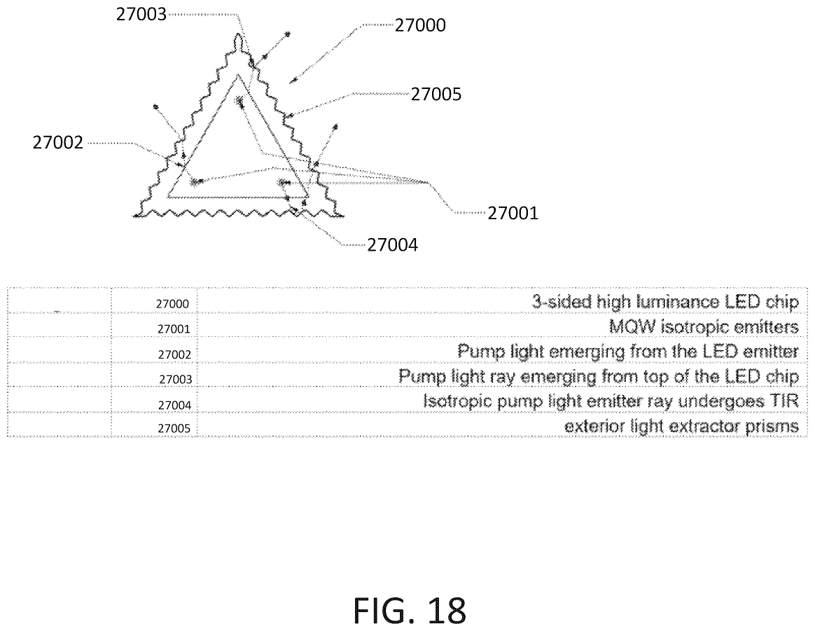

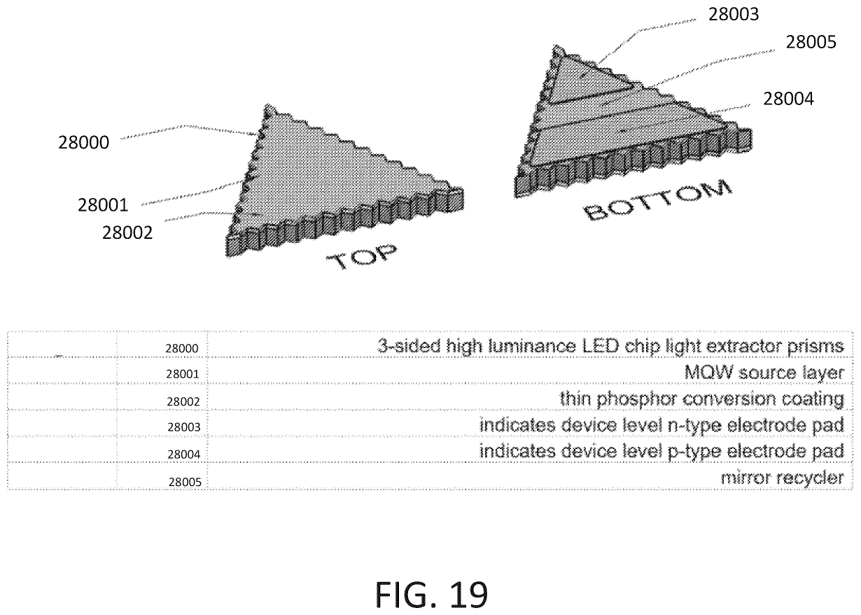

Referring now to FIG. 18, a horizontal structure of a 3-sided LED chip geometry 27000 includes a triangle primitive enhanced with exterior light extractor prisms 27005 of the LED mesa during the dicing process. Light is produced by means of a multi-quantum well (MOW) stack 27001 in which the emerging pump light 27002 passes through the phosphor layer and exits through the sides. Some pump light 27003 and wavelength converted light may have secondary opportunity for recycling by means of total internal reflection (TIR) 27004. Although the combination of light extractor and lateral DBR structures aid in confining the blue pump light emerging through the top of the chip through the phosphor layer, the micro-prism structure 27005 helps wick the light out of the phosphor layer. FIG. 19 depicts a vertical or three dimensional structure of a 3-sided LED chip 28000 in which the triangle primitive is enhanced with side light extractor prisms. The light production begins with a MOW source layer 28001 electrified by means of a p-type 28004 and n-type 28003 electrode pads. Light emerging from the source layer 28001 emerges both upward and downward. The downward light may be recycled upwards by means of the mirror recycler 28005. Light exits the n-type and undoped GaN layers to enter through the 28002 phosphor conversion layer 28002, which converts the violet, blue or cyan light from the source layer 28001 into broad band white light.

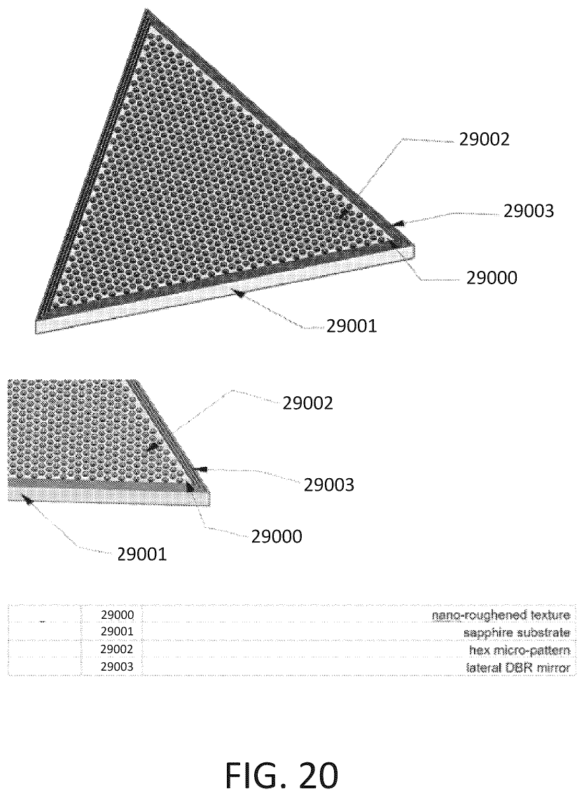

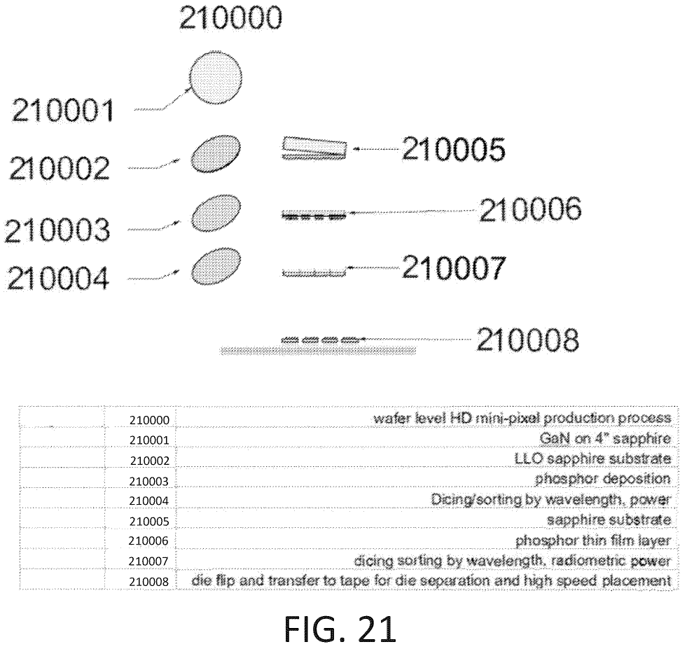

Referring now to FIG. 20, an alternate construction includes a nano-roughened texture 29000 upon the 3-sided sapphire substrate 29001 chip to help reduce threading dislocations in undoped and n-type GaN. The combined optical features of the hexagonal micro pattern 29002 and the DBR improve both growth external quantum and provide lateral energy confinement thereby improving luminance off the chip. FIG. 21 depicts the process 210000 by which the chips 27000, 28000, 29000 are produced. First, GaN is grown on a, for example, 4 inch sapphire substrate 210001 in which the sapphire is modified with combinations of nano-roughening, micro light extractors, or lateral energy confinement features. Laser lift off (LLO) at 210002 removes the sapphire substrate at 210005 leaving free-standing GaN active layers including the lateral confinement DBR. Next, deposition of phosphor at 210003 provides for conversion of the blue pump light to wide spectrum white. The wafer is then diced at 210007 and sorted at 210004 by wavelength and radiometric power, and voltage. Next, the phosphor thin film layer 210006 is adhered to an adhesive such as tape for die separation (stretch) and preparation for high speed placement at 210008.

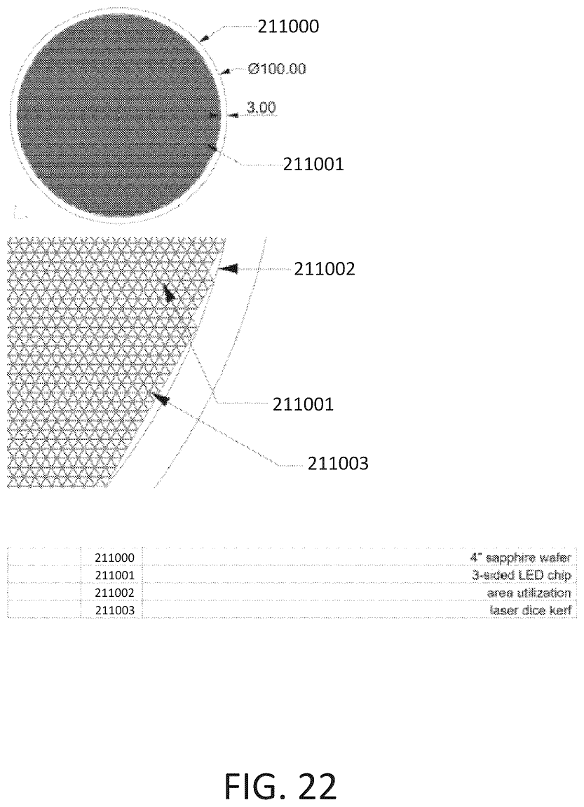

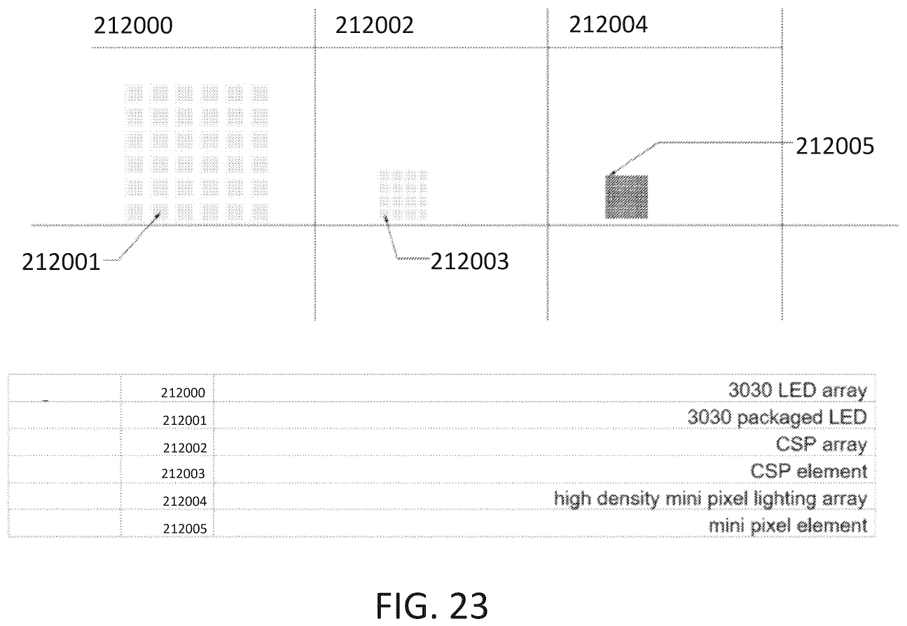

FIG. 22 illustrates the device design and dicing pattern in which the wafer 211000 is cut to produce higher yield/wafer of 3-sided chips 211001 for equivalent area of the chip. The active wafer area utilization 211002 increased and laser dice kerf is kept to a minimum 211003. FIG. 23 illustrates how the drive to produce higher luminance/chip has progressed from the larger array 212000 with low cost 3030 LED package 212001, in which the chip is converted to white by means of a tub of phosphor, to the CSP array 212002, in which each CSP chip element 12003 is arrayed into an x,y pattern for illumination. Implementations herein include an improvement for increasing the number of elements/unit area which can be powered with a high density pixel lighting array 212004 that includes many mini pixel elements 212005.

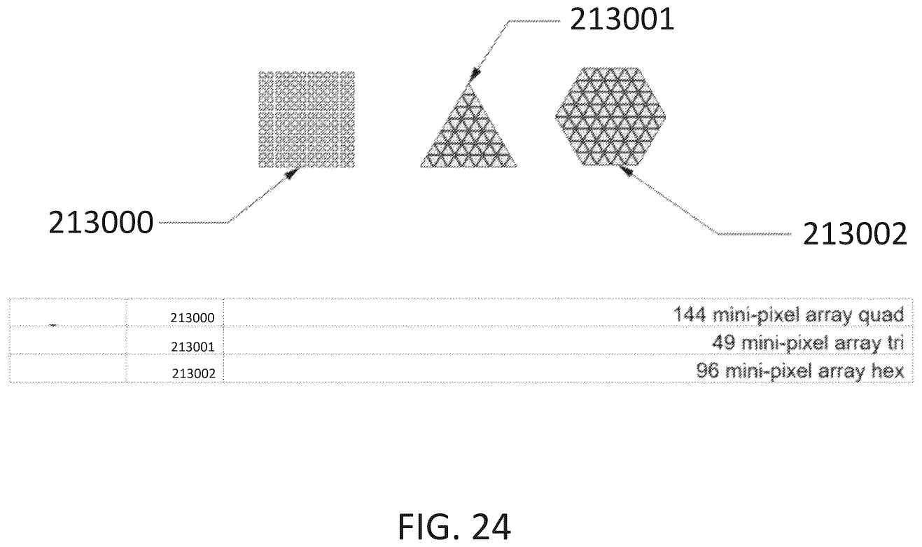

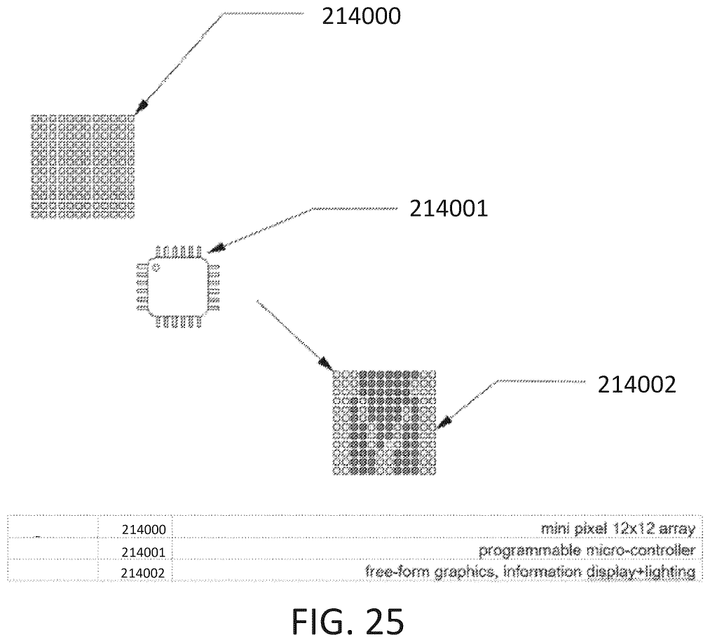

Referring now to FIG. 24, alternate arrangements where, instead of multiple square or rectangular elements arranged to form an individually addressable array 213000 including 144 mini pixels, a 3-sided device structure array pattern allows for triangular array 213001 elements including 49 mini pixels, each of which may be patterned into other shapes and configurations. For example, the shapes include 6-sided clusters such as 213002 that include 96 mini-pixel 3-sided elements. FIG. 25 illustrates how a square mini pixel array 214000 comprised of 12×12 elements may be controlled via a programmable micro-controller 214001 to produce free-form graphics, information display (e.g., lettering and figures), and lighting functions.

Optionally, the system may include a display for displaying images captured by one or more of the imaging sensors for viewing by the driver of the vehicle while the driver is normally operating the vehicle. Optionally, for example, the vision system may include a video display device, such as by utilizing aspects of the video display systems described in U.S. Pat. Nos. 5,530,240; 6,329,925; 7,855,755; 7,626,749; 7,581,859; 7,446,650; 7,338,177; 7,274,501; 7,255,451; 7,195,381; 7,184,190; 5,668,663; 5,724,187; 6,690,268; 7,370,983; 7,329,013; 7,308,341; 7,289,037; 7,249,860; 7,004,593; 4,546,551; 5,699,044; 4,953,305; 5,576,687; 5,632,092; 5,708,410; 5,737,226; 5,802,727; 5,878,370; 6,087,953; 6,173,501; 6,222,460; 6,513,252 and/or 6,642,851, and/or U.S. Publication Nos. US-2014-0022390; US-2012-0162427; US-2006-0050018 and/or US-2006-0061008, which are all hereby incorporated herein by reference in their entireties.

Optionally, the display may be viewable through a reflective element of a mirror assembly when the display is activated to display information. Optionally, the display element may comprise any type of display element, such as a vacuum fluorescent (VF) display element, a light emitting diode (LED) display element, such as an organic light emitting diode (OLED) or an inorganic light emitting diode, an electroluminescent (EL) display element, a liquid crystal display (LCD) element, a video screen display element or backlit thin film transistor (TFT) display element or the like, and may be operable to display various information (as discrete characters, icons or the like, or in a multi-pixel manner) to the driver of the vehicle, such as passenger side inflatable restraint (PSIR) information, tire pressure status, and/or the like.

Changes and modifications in the specifically described embodiments can be carried out without departing from the principles of the invention, which is intended to be limited only by the scope of the appended claims, as interpreted according to the principles of patent law including the doctrine of equivalents.

What is claimed is:

1. A lighting system comprising:
at least one light emitting diode chip configured as a triangle primitive in an x-y direction and defining a thickness in a z direction, the at least one light emitting diode chip comprising:
a multi-quantum well (MQW) stack electrified by a p-type material, an n-type material, and a plurality of electrodes, the p-type material and the n-type material each positioned on a first side of the MQW stack;
a light wicking prism structure defining a boundary around the at least one light emitting diode chip; and
a transition positioned between the MQW stack and the light wicking prism structure.

2. The lighting system of claim 1, wherein the transition includes a layer of phosphor and an encapsulation material.

3. The lighting system of claim 1, wherein the transition defines a sapphire to air interface.

4. The lighting system of claim 1, wherein the MQW stack produces light that exits through a peripheral side of the triangle primitive and towards an interior side of the light wicking prism structure.

5. The lighting system of claim 1, wherein the p-type material defines a first area on the first side of the MQW stack and the n-type material defines a second area on the first side of the MQW stack, the second area less than the first area.

6. The lighting system of claim 1, further comprising:
a distributed Bragg reflector (DBR) mirror configured to increase luminance and force light upward through a thin film phosphor layer.

7. The lighting system of claim 6, wherein the DBR mirror is positioned below the MQW stack, and wherein the DBR mirror is produced by alternating high and low refractive index materials.

8. The lighting system of claim 1, wherein the triangle primitive further includes one or more nano-structure light extraction elements.

9. The lighting system of claim 1, wherein the triangle primitive further includes one or more nano-porous light confinement structures.

10. A lighting system comprising:
a first light emitting diode chip configured as a triangle primitive in an x-y direction and defining a thickness in a z direction, the first light emitting diode chip comprising:
a multi-quantum well (MQW) stack electrified by a p-type material, an n-type material, and a plurality of electrodes, the p-type material and the n-type material each positioned on a first side of the MQW stack;
a light wicking prism structure defining a boundary around the first light emitting diode chip; and
a distributed Bragg reflector (DBR) mirror positioned below the MQW stack, wherein the DBR mirror is produced by alternating high and low refractive index materials.

11. The lighting system of claim 10, wherein the first light emitting diode chip further comprises:
a transition positioned between the MQW stack and the light wicking prism structure.

12. The lighting system of claim 10, wherein the p-type material defines a first area on the first side of the MQW stack and the n-type material defines a second area on the first side of the MQW stack, the second area less than the first area.

13. The lighting system of claim 10, wherein the p-type material defines a first geometric shape on the first side of the MQW stack and the n-type material defines a second geometric shape on the first side of the MQW stack, the second geometric shape varied from the first geometric shape.

14. The lighting system of claim 10, further comprising:
a second light emitting diode chip configured as a triangle primitive in an x-y direction and defining a thickness in a z direction, wherein the first light emitting diode chip and the second light emitting diode chip are individually addressed via a programmable micro-controller.

15. The lighting system of claim 10, wherein the triangle primitive further includes one or more nano-structure light extraction elements.

16. A lighting system comprising:
at least one light emitting diode chip configured as a triangle primitive in an x-y direction and defining a thickness in a z direction, the at least one light emitting diode chip comprising:
a MQW stack electrified by a p-type material, an n-type material, and a plurality of electrodes, the p-type material and the n-type material each positioned on a first side of the MQW stack; and
a mirror recycler positioned along a second side of the second side of the MQW stack, wherein light emitted in a downward direction by the MQW stack is recycled by the mirror recycler.

17. The lighting system of claim 16, further comprising:
a light wicking prism structure defined by the at least one light emitting diode chip to encourage lateral light emerging from isotropic emitters of the at least one light emitting diode chip.

18. The lighting system of claim 17, further comprising:
a transition positioned between the MQW stack and the light wicking prism structure.

19. The lighting system of claim 18, wherein the transition includes a layer of phosphor and an encapsulation material.

20. The lighting system of claim 18, wherein the transition defines a sapphire to air interface.
